(19) United States
(12) Patent Application Publication
(10) Pub. No.: US 2012/0122031 A1
(43) Pub. Date: May 17, 2012

(54) PHOTORESIST COMPOSITION FOR NEGATIVE DEVELOPMENT AND PATTERN FORMING METHOD USING THEREOF

(75) Inventors: Kuang-Jung Chen, Poughkeepsie, NY (US); Sen Liu, Highland Park, NJ (US); Wu-Song Huang, Brewster, NY (US); Wai-Kin Li, Beacon, NY (US)

(73) Assignee: INTERNATIONAL BUSINESS MACHINES CORPORATION, Armonk, NY (US)

(21) Appl. No.: 12/946,232

(22) Filed: Nov. 15, 2010

(51) Int. Cl. G03F 7/004; G03F 7/20

(52) U.S. Cl. 430/280.1; 430/270.1; 430/324

(57) ABSTRACT

The present invention relates to a photoresist composition capable of negative development and a pattern forming method using the photoresist composition. The photoresist composition includes an imaging polymer and a radiation sensitive acid generator. The imaging polymer includes a first monomeric unit having a pendant acid labile moiety and a second monomeric unit containing a reactive ether moiety, an isocyanide moiety or an isocyanate moiety. The patterning forming method utilizes an organic solvent developer to selectively remove unexposed regions of a photoresist layer of the photoresist composition to form a patterned structure in the photoresist layer. The photoresist composition and the pattern forming method are especially useful for forming material patterns on a semiconductor substrate using 193 nm (ArF) lithography.

### FIELD OF THE INVENTION

This invention relates generally to photolithography, and more particularly to a photoresist composition capable of negative development using an organic solvent as the developer. This invention is also directed to a pattern forming method of using such a photoresist composition.

### BACKGROUND OF THE INVENTION

Photolithography is a process which uses light to transfer a geometric pattern from a photomask to a substrate such as a silicon wafer. In a photolithography process, a photoresist layer is first formed on the substrate. The substrate is baked to remove any solvent remained in the photoresist layer. The photoresist is then exposed through a photomask with a desired pattern to a source of actinic radiation. The radiation exposure causes a chemical reaction in the exposed areas of the photoresist and creates a latent image corresponding to the mask pattern in the photoresist layer. The photoresist is next developed in a developer solution, usually an aqueous base solution, to form a pattern in the photoresist layer. The patterned photoresist can then be used as a mask for subsequent fabrication processes on the substrate, such as deposition, etching, or ion implantation processes.

There are two types of photoresist: positive resist and negative resist. A positive resist is initially insoluble in the developer solution. After exposure, the exposed region of the resist becomes soluble in the developer solution and is then selectively removed by the developer solution during the subsequent development step. The unexposed region of the positive resist remains on the substrate to form a pattern in the photoresist layer. The selective removal of the exposed region of a photoresist is thus called “positive development”.

A negative resist behaves in the opposite manner. The negative resist is initially soluble in the developer solution. Exposure to radiation typically initiates a crosslinking reaction which causes the exposed region of the negative resist to become insoluble in the developer solution. During the subsequent development step, the unexposed region of the negative resist is selectively removed by the developer solution, leaving the exposed region on the substrate to form a pattern. Contrary to the “positive development”, a “negative development” refers to a process that selectively removes the unexposed region of a photoresist.

Most commercial photoresists for 193 nm photolithography are positive resists. However, as semiconductor ground rule gets smaller, it has become ever more challenging to print small features such as trenches and vias of small dimensions using traditional positive resist with aqueous base developer due to the poor optical image contrast of the dark field masks used to create the trenches and vias. Therefore, there is a need for a photoresist composition and a pattern forming method that can print small features, particularly trenches and vias of small dimensions.

### SUMMARY OF THE INVENTION

The present invention provides a photoresist composition which is capable of negative development using an organic solvent developer. This invention also provides a pattern forming method which is capable of printing trenches and vias of small dimensions.

In one aspect, the present invention relates to a photoresist composition capable of negative development. The composition includes an imaging polymer and a radiation sensitive acid generator. The imaging polymer includes a first monomeric unit having a pendant acid labile moiety and a second monomeric unit containing a reactive ether moiety, an isocyanide moiety or an isocyanate moiety.

In another aspect, the present invention relates to a photoresist composition capable of negative development. The composition includes a polymer, a radiation sensitive acid generator and a component. The polymer contains a monomeric unit having a pendant acid labile moiety. The component contains an alcohol moiety, a reactive ether moiety, an isocyanide moiety or an isocyanate moiety.

In still another aspect, the present invention relates to a method of forming a patterned material structure on a substrate. The method includes the steps of: providing a substrate with a layer of the material; applying a photoresist composition to the substrate to form a photoresist layer over the material layer, the photoresist composition comprising an imaging polymer and a radiation sensitive acid generator, the imaging polymer comprising a first monomeric unit having a pendant acid labile moiety and a second monomeric unit containing a primary alcohol moiety, a secondary alcohol moiety, a reactive ether moiety, an isocyanide moiety or an isocyanate moiety; patternwise exposing the substrate to radiation whereby acid is generated by the radiation sensitive acid generator in exposed regions of the photoresist layer by the radiation; and contacting the photoresist layer with a developer comprising an organic solvent whereby unexposed regions of the photoresist layer are selectively removed by the developer solution to form a patterned structure in the photoresist layer.

In still another aspect, the present invention relates to a method of forming a patterned material structure on a substrate. The method includes the steps of: providing a substrate with a layer of the material; applying a photoresist composition to the substrate to form a photoresist layer over the material layer, the photoresist composition comprising a polymer, a radiation sensitive acid generator and a component, the polymer comprising a monomeric unit having a pendant acid labile moiety, and the component comprising an alcohol moiety, a reactive ether moiety, an isocyanide moiety or an isocyanate moiety; patternwise exposing the substrate to radiation whereby acid is generated by the radiation sensitive acid generator in exposed regions of the photoresist layer by the radiation; and contacting the photoresist layer with a developer comprising an organic solvent whereby unexposed regions of the photoresist layer are selectively removed by the developer solution to form a patterned structure in the photoresist layer.

### DETAILED DESCRIPTION OF PREFERRED EMBODIMENTS

It will be understood that when an element, such as a layer, is referred to as being “on” or “over” another element, it can be directly on the other element or intervening elements may also be present. In contrast, when an element is referred to as being “directly on” or “directly over” another element, there are no intervening elements present.

As discussed above, most commercial photoresists for 193 nm photolithography are positive resists. As the feature size becomes smaller and smaller, it has become more difficult to print trenches and vias of small dimensions using traditional positive resists. To create trenches and vias with positive resists, dark field masks need to be used. However, the optical image contrast of the dark field masks diminishes as the feature sizes of the trenches and vias decrease.

On the other hand, trenches and vias can be printed with negative resists using bright field mask. The optical image contrast of the bright field masks is better than that of the dark filed masks. Hence, it may be advantageous to print trenches and vias of small using negative resists. However, traditional negative resists often suffer from poor resolution and microbridging because they are based on crosslinking upon exposure to create dissolution contrast with alkaline developer for image formation.

Recently, a pattern forming method using traditional positive resists for negative development has gained fraction. Like traditional approaches using positive resists, this method relies on the de-protection mechanism to create dissolution contrast between exposed and unexposed regions in the photoresist layer. However, instead of aqueous alkaline developer, an organic solvent is then used in this method as the developer for negative development which selectively removes the unexposed regions of the photoresist layer. Since the resist in the exposed regions often has some solubility in the organic solvent developer, this method may suffer from thickness loss after the development step.

The present invention provides a photoresist composition for negative development which can be used to print trenches and vias of small dimensions. The composition in the present invention combines the deprotection mechanism with the crosslinking mechanism to achieve high dissolution contrast between the exposed and unexposed regions, and in the mean time, to prevent thickness loss of the photoresist layer during the development step. This is accomplished through incorporating both an acid labile moiety and a crosslinkable moiety in the photoresist composition.

In one embodiment, the photoresist composition of the present invention includes an imaging polymer and a radiation sensitive acid generator. The imaging polymer includes a first monomeric unit having a pendant acid labile moiety and a second monomeric unit containing a crosslinkable moiety. The first and second monomeric units are derived from monomers having a polymerizable moiety. Examples of the polymerizable moiety may include:

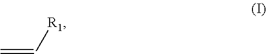

where R₁ represents hydrogen, a linear or branched alkyl group of 1 to 20 carbons, a semi- or perfluorinated linear or branched alkyl group of 1 to 20 carbons, or CN; and

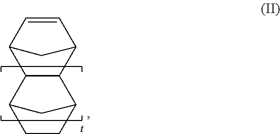

where t is an integer from 0 to 3.

The acid labile moiety in the first monomeric unit may be one of a tertiary alkyl carbonate, a tertiary alkyl ester, a tertiary alkyl ether, an acetal and a ketal. Preferably, the acid labile moiety in the first monomeric unit is a tertiary alkyl ester. Examples of monomers from which the first monomeric unit can derive from may include, but are not limited to:

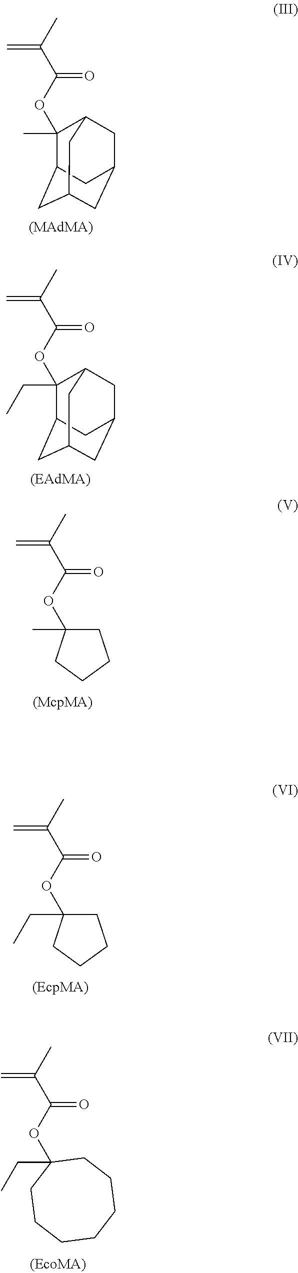

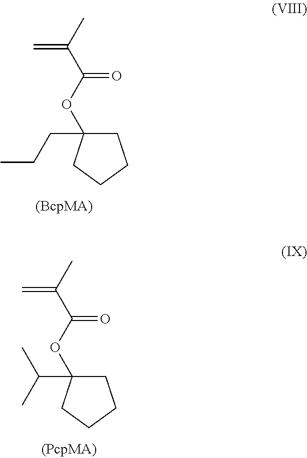

The second monomeric unit contains a crosslinkable moiety such as a reactive ether moiety, an isocyanide moiety or an isocyanate moiety. Preferably, the reactive ether moiety is epoxide. The crosslinkable moiety can react with the deprotected first monomeric unit and/or another crosslinkable moiety to crosslink the imaging polymer. Examples of monomers from which the second monomeric unit can derive from may include, but are not limited to:

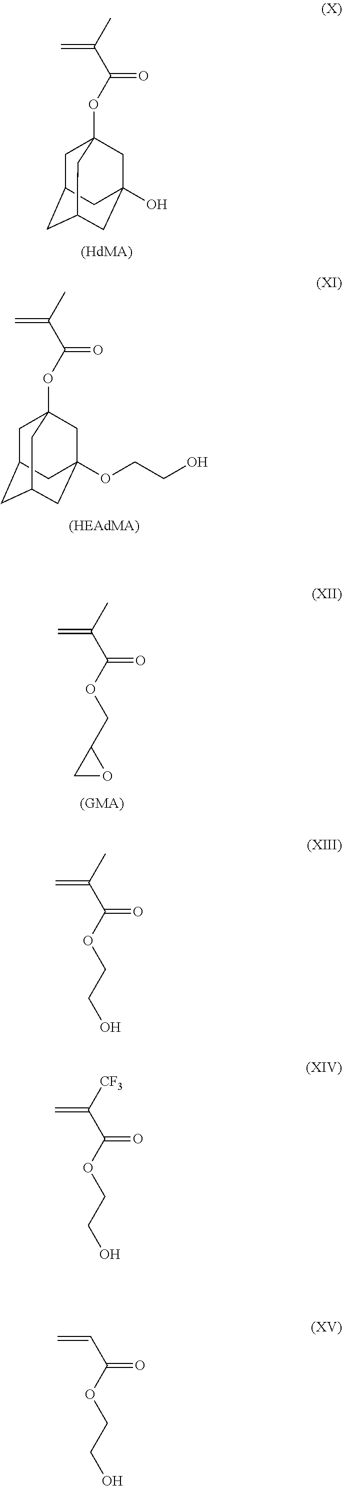

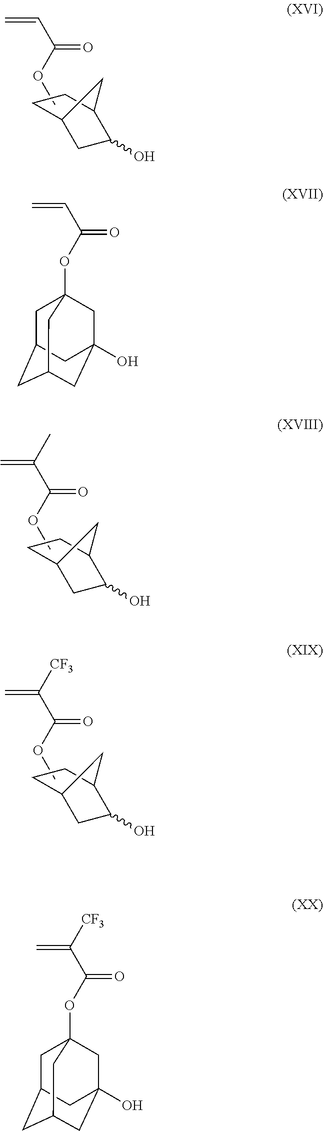

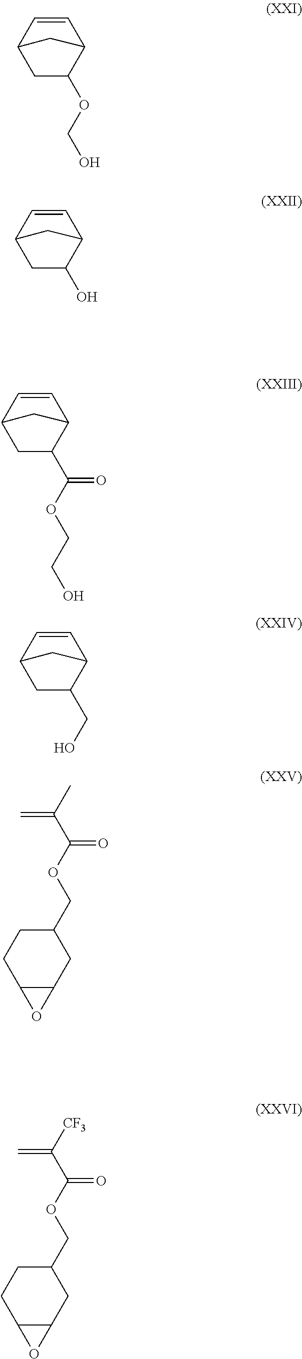

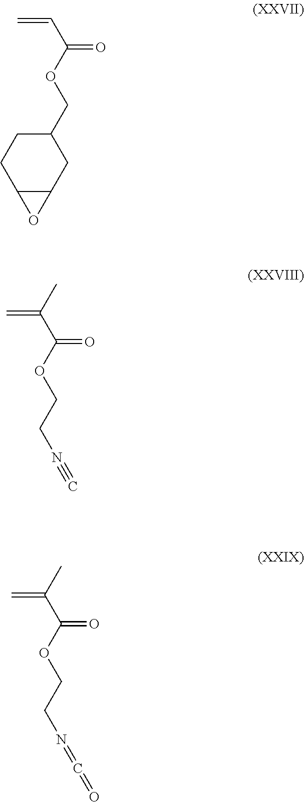

Optionally, the imaging polymer of the present invention may include a third monomer unit which allows for further regulation of, for example, dissolution properties, thermal properties, and etch resistance in various exemplary embodiments. Preferably, the third monomer unit contains a lactone moiety. Examples of such a third monomer may include, but are not limited to:

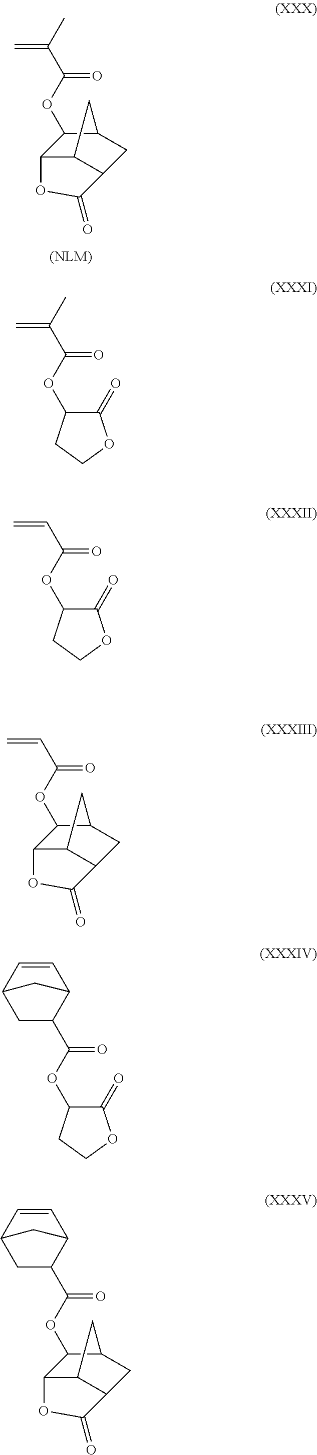

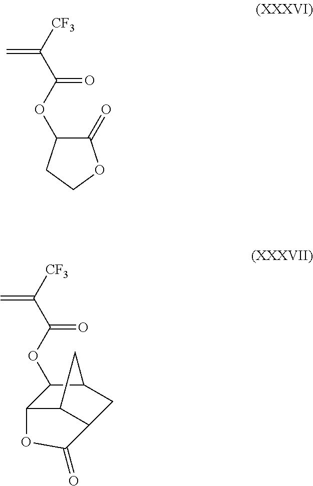

The radiation sensitive acid generator, also known as photoacid generator (PAG), is a compound that generates an acid upon exposure to radiation. The PAG of the present invention may be one of an onium salt, a succinimide derivative, a diazo compound, a nitrobenzyl compound, and the like. To minimize acid diffusion for high resolution capability, the PAGs may be such that they generate bulky acids upon exposure to radiation. Such bulky acids may include at least 4 carbon atoms.

A preferred PAG that may be employed in the present invention is an onium salt, such as an iodonium salt or a sulfonium salt, and/or a succinimide derivative. In various exemplary embodiments of the present invention, the preferred PAG may include 4-(1-butoxynaphthyl) tetrahydrothiophenium perfluorobutanesulfonate, triphenyl sulfonium perfluorobutanesulfonate, t-butylphenyl diphenyl sulfonium perfluorobutanesulfonate, 4-(1-butoxynaphthyl) tetrahydrothiophenium perfluorooctanesulfonate, triphenyl sulfonium perfluorooctanesulfonate, t-butylphenyl diphenyl sulfonium perfluorooctanesulfonate, di(t-butylphenyl) iodonium perfluorobutane sulfonate, di(t-butylphenyl) iodonium perfluorohexane sulfonate, di(t-butylphenyl) iodonium perfluoroethylcyclohexane sulfonate, di(t-buylphenyl)iodonium camphoresulfonate, and perfluorobutylsulfonyloxybicylo[2.2.1]-hept-5-ene-2,3-dicarboximide. Any of these PAGs may be used singly or in a mixture of two or more. Both fluorinated and fluorine-free PAGs can be used in the present invention.

The specific PAG selected will depend on the irradiation being used for patterning the photoresist. PAGs are currently available for a variety of different wavelengths of light from the visible range to the extreme UV range. Preferably, the PAG is one suitable for use in 193 nm (ArF) lithography.

The photoresist composition of the present invention may further include a solvent, and other performance enhancing additives, for example, a quencher and a surfactant. Solvents well known to those skilled in the art may be employed in the photoresist composition of various exemplary embodiments of the present invention. Such solvents may be used to dissolve the imaging polymer and other components of the photoresist composition. Illustrative examples of such solvents may include, but are not limited to: ethers, glycol ethers, aromatic hydrocarbons, ketones, esters and the like. A solvent system including a mixture of the aforementioned solvents is also contemplated. Suitable glycol ethers include: 2-methoxyethyl ether (diglyme), ethylene glycol monomethyl ether, propylene glycol monomethyl ether, propylene glycol monomethylether acetate (PGMEA) and the like. Suitable aromatic hydrocarbon solvents include: toluene, xylene, and benzene. Examples of ketones include: methylisobutylketone, 2-heptanone, cycloheptanone, and cyclohexanone. An example of an ether solvent is tetrahydrofuran, whereas ethyl lactate and ethoxy ethyl propionate are examples of ester solvents that may be employed in the present invention.

The quencher that may be used in the photoresist composition of the present invention may comprise a weak base that scavenges trace acids, while not having an excessive impact on the performance of the positive photoresist. Illustrative examples of quenchers that can be employed in the present invention include, but are not limited to: aliphatic amines, aromatic amines, carboxylates, hydroxides, or combinations thereof and the like.

The optional surfactants that can be employed in the photoresist compositions include any surfactant that is capable of improving the coating homogeneity of the chemically amplified photoresist composition of the present invention. Illustrative examples include: fluorine-containing surfactants such as 3M's FC-4430® and siloxane-containing surfactants such as Union Carbide's Silwet® series.

In addition to the above components, the photoresist composition may also include other components such as photosensitizers and/or other additives. If desired, combinations or mixtures of the components may be used (e.g., a photosensitizer and a base). The optional photosensitizer is preferably one containing chromophores that are capable of absorbing irradiation in 193 nm (ArF) lithography. Illustrative examples of such compounds include, but are not limited to: 9-anthracene methanol, coumarins, 9,10-bis(trimethoxysily ethynyl) anthracene and polymers containing these chromophores.

In various exemplary embodiments of the present invention, the photoresist composition of the invention may include: about 1 to about 30 wt. % of the imaging polymer, more preferably about 3 to about 15 wt. %; about 0.5 to about 30 wt. % of the radiation sensitive acid generator, based on the total weight of the imaging polymer, more preferably about 0.5 to about 15 wt. %; and a solvent, which may typically be present in amounts of about 70 to about 99 wt. % of the composition, more preferably about 85 to about 97 wt. %.

In various exemplary embodiments, the photoresist composition may further comprise a quencher, which may typically be present in amounts of about 0.1 to about 10.0 wt. % based on the total weight of the imaging polymer, and a surfactant, which may typically be present in amounts of about 0.001 to about 1.0 wt. %, based on the total weight of the imaging polymer. When a photosensitizer is employed, it is preferably present in amounts of about 0.001 to about 8 weight %, based on the total weight of the imaging polymer.

Note that the amounts given above are exemplary and that other amounts of each of the above components, which are typically employed in the photolithography industry, can also be employed herein.

In another embodiment, the photoresist composition of the present invention includes a polymer, a radiation sensitive acid generator and a component. The polymer includes a monomeric unit having a pendant acid labile moiety. The component includes a crosslinkable moiety such as an alcohol moiety, a reactive ether moiety, an isocyanide moiety or an isocyanate moiety.

The monomeric unit with a pendant acid labile may be the same as the first monomeric unit described above. Thus, all examples of the first monomers given above can be used to form the monomeric unit. Similarly, the radiation sensitive acid generator may be the same as the radiation sensitive acid generators in various exemplary embodiments described above.

The component containing a crosslinkable moiety may be a polymer or a small compound. The component can react with the deprotected monomeric unit on the polymer to crosslink the polymer. The alcohol moiety on the component may be a primary alcohol, a secondary alcohol, or a tertiary alcohol group. The reactive ether moiety on the component is preferably epoxide. When the component is a polymer, the polymer component contains at least one monomeric unit having an alcohol moiety, a reactive ether moiety, an isocyanide moiety or an isocyanate moiety. An example of such a polymer component is a homopolymer of GMA. When the component is a small compound, it preferably contains at least two crosslinkable moieties. Examples of such a small compound component may include:

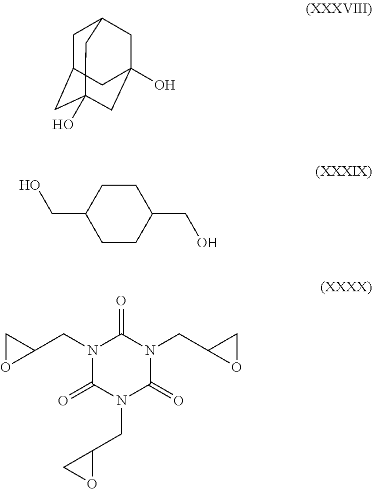

The photoresist composition may further include a solvent, and other performance enhancing additives, for example, a quencher, a surfactant and a photosensitizer, such as in various exemplary embodiments described above.

In various exemplary embodiments of the present invention, the photoresist composition of the invention may include: about 1 to about 30 wt. % of the polymer, more preferably about 3 to about 15 wt. %; about 0.5 to about 30 wt. % of the radiation sensitive acid generator, based on the total weight of the polymer, more preferably about 0.5 to about 15 wt. %; about 1 to about 30 wt. % of the component, based on the total weight of the polymer, more preferably about 2 to about 10 wt. %; and a solvent, which may typically be present in amounts of about 70 to about 99 wt. % of the composition, more preferably about 85 to about 97 wt. %.

In various exemplary embodiments, the photoresist composition may further comprise a quencher, which may typically be present in amounts of about 0.1 to about 10.0 wt. % based on the total weight of the polymer, and a surfactant, which may typically be present in amounts of about 0.001 to about 1.0 wt. %, based on the total weight of the polymer. When a photosensitizer is employed, it is preferably present in amounts of about 0.001 to about 8 weight %, based on the total weight of the polymer.

The present invention also encompasses a method of using the photoresist compositions described to form patterned material features on a substrate. In one embodiment, such a method includes the steps of: providing a substrate with a layer of the material; applying a photoresist composition to the substrate to form a photoresist layer over the material layer, the photoresist composition comprising an imaging polymer and a radiation sensitive acid generator, the imaging polymer comprising a first monomeric unit having a pendant acid labile moiety and a second monomeric unit containing a primary alcohol moiety, a secondary alcohol moiety, a reactive ether moiety, an isocyanide moiety or an isocyanate moiety; patternwise exposing the substrate to radiation whereby acid is generated by the radiation sensitive acid generator in exposed regions of the photoresist layer by the radiation; and contacting the photoresist layer with a developer comprising an organic solvent whereby unexposed regions of the photoresist layer are selectively removed by the developer solution to form a patterned structure in the photoresist layer.

In another embodiment, such a method includes the steps of: providing a substrate with a layer of the material; applying a photoresist composition to the substrate to form a photoresist layer over the material layer, the photoresist composition comprising a polymer, a radiation sensitive acid generator and a component, the polymer comprising a monomeric unit having a pendant acid labile moiety, and the component comprising an alcohol moiety, a reactive ether moiety, an isocyanide moiety or an isocyanate moiety; patternwise exposing the substrate to radiation whereby acid is generated by the radiation sensitive acid generator in exposed regions of the photoresist layer by the radiation; and contacting the photoresist layer with a developer comprising an organic solvent whereby unexposed regions of the photoresist layer are selectively removed by the developer solution to form a patterned structure in the photoresist layer.

In various exemplary embodiments of the present invention, the substrate is suitably any substrate conventionally used in processes involving photoresists. For example, the substrate can be silicon, silicon oxide, aluminum-aluminum oxide, gallium arsenide, ceramic, quartz, copper or any combination thereof, including multilayers. The substrate can include one or more semiconductor layers or structures and can include active or operable portions of semiconductor devices.

The material layer may be a metal conductor layer, a ceramic insulator layer, a semiconductor layer or other material depending on the stage of the manufacture process and the desired material set for the end product. The photoresist compositions of the invention are especially useful for lithographic processes used in the manufacture of integrated circuits on semiconductor substrates. The photoresist compositions of the invention can be used in lithographic processes to create patterned material layer structures such as metal wiring lines, holes for contacts or vias, insulation sections (e.g., damascene trenches or shallow trench isolation), trenches for capacitor structures, ion implanted semiconductor structures for transistors, etc. as might be used in integrated circuit devices.

In some cases, a bottom antireflective coating and/or underlayer coating (e.g., a planarizing underlayer) may be applied between the photoresist layer and the material layer. In other cases, a top antireflective coating layer may be applied over the photoresist layer. The invention is not limited to the use of antireflective reflective coatings and/or underlayer materials, nor specific compositions of those coatings or materials.

The photoresist layer may be formed by virtually any standard means including spin coating. The photoresist layer may be baked (post applying bake (PAB)) to remove any solvent from the photoresist and improve the coherence of the photoresist layer. The preferred range of the PAB temperature for the photoresist layer is from about 70° C. to about 150° C., more preferably from about 90° C. to about 130° C. The preferred range of thickness of the first layer is from about 20 nm to about 400 nm, more preferably from about 30 nm to about 300 nm.

The photoresist layer is then patternwise exposed to the desired radiation. The radiation employed in the present invention can be visible light, ultraviolet (UV), extreme ultraviolet (EUV) and electron beam (E-beam). It is preferred that the imaging wavelength of the radiation is about 248 nm, 193 nm or 13 nm. It is more preferred that the imaging wavelength of the radiation is about 193 nm (ArF laser). The patternwise exposure is conducted through a mask which is placed over the photoresist layer.

After the desired patternwise exposure, the photoresist layer is typically baked (post exposure bake (PEB)) to further complete the acid-catalyzed reaction and to enhance the contrast of the exposed pattern. The preferred range of the PEB temperature is from about 70° C. to about 150° C., more preferably from about 90° C. to about 130° C. In some instances, it is possible to avoid the PEB step since for certain chemistries, such as acetal and ketal chemistries, deprotection of the resist polymer proceeds at room temperature. The post-exposure bake is preferably conducted for about 30 seconds to 5 minutes.

After PEB, if any, the photoresist structure with the desired pattern is obtained (developed) by contacting the photoresist layer with a developer comprising an organic solvent. Preferably, the developer is selected from the group consisting of ethers, glycol ethers, aromatic hydrocarbons, ketones, esters and a combination of two or more of the foregoing solvents. Suitable glycol ethers include: 2-methoxyethyl ether (diglyme), ethylene glycol monomethyl ether, propylene glycol monomethyl ether, propylene glycol monomethylether acetate (PGMEA) and the like. Suitable aromatic hydrocarbon solvents include: toluene, xylene, and benzene. Examples of ketones include: methylisobutylketone, 2-heptanone, cycloheptanone, and cyclohexanone. An example of an ether solvent is tetrahydrofuran, whereas ethyl lactate, n-butyl acetate and ethoxy ethyl propionate (EEP) are examples of ester solvents that may be employed in the present invention. More preferably, the developer is 2-heptanone, PGMEA, or EEP. The developer selectively dissolves the areas of the photoresist which were unexposed to the radiation. Hence, the development step in the present invention is a “negative development” step.

Optionally, the method of the present invention may further include a step of rinsing the photoresist layer with a second organic solvent after the development step. After resist development, some residues may remain on the substrate due to its low solubility in developer. Rinse with the second organic solvent removes these residues and provides clean resist images. Preferably, the second organic solvent has a slightly higher polarity than the developer. Examples of such a second organic solvent may include, but are not limited to: 1-butanol, methanol, ethanol, 1-propanol, ethylene glycol, 1,2-butanediol, 1,3-butanediol, 1,4-butanediol, 1,2-propanediol, 1-methyl-2-butanol, 1-pentanol, 2-pentanol, 3-pentanol, 1-hexanol, 2-hexanol, 3-hexanol, 1-heptanol, 2-heptanol, 3-heptanol, 4-heptanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 2,4-dimethyl-3-pentanol, 3-ethyl-2-pentanol, 1-methylcyclopentanol, 2-methyl-1-hexanol, 2-methyl-2-hexanol, 2-methyl-3-hexanol, 3-methyl-3-hexanol, 4-methyl-3-hexanol, 5-methyl-1-hexanol, 5-methyl-2-hexanol, 5-methyl-3-hexanol, 4-methylcyclohexanol, 1,3-propanediol, and a combination of two or more of the foregoing solvents.

The pattern from the photoresist structure may then be transferred to the exposed portions of underlying material layer of the substrate by etching with a suitable etchant using techniques known in the art; preferably the transfer is done by reactive ion etching or by wet etching. Once the desired pattern transfer has taken place, any remaining photoresist may be removed using conventional stripping techniques. Alternatively, the pattern may be transferred by ion implantation to form a pattern of ion implanted material.

Examples of general lithographic processes where the composition of the invention may be useful are disclosed in U.S. Pat. Nos. 4,855,017; 5,362,663; 5,429,710; 5,562,801; 5,618,751; 5,744,376; 5,801,094; 5,821,469 and 5,948,570. Other examples of pattern transfer processes are described in Chapters 12 and 13 of “Semiconductor Lithography, Principles, Practices, and Materials” by Wayne Moreau, Plenum Press, (1988). It should be understood that the invention is not limited to any specific lithography technique or device structure.

The invention is further described by the examples below. The invention is not limited to the specific details of the examples.

### Example 1

### Resist A Formulation

A tetrapolymer consisting of 10 mole % McpMA, 40 mole % MAdMA, 15 mole % HAdMA and 35 mole % NLM was dissolved in PGMEA with 30 wt % GBL(γ-butyrolactone), 2 wt % triphenyl-sulfonium 2-bicyclo[2.2.1]hept-7-yl-1,1,2,2-tetrafluoro-ethanesulfonate, 5 wt % (4-cyclohexyl-phenyl)-diphenyl-sulfonium 1,1,2,2,3,3,4,4,4-nonafluoro-butane-1-sulfonate and 0.69 wt % of 2-hydroxymethyl-pyrrolidine-1-carboxylic acid tert-butyl ester (all wt % are relative to the polymer) to make a solution with 4 wt % of solid content. The resulting solution was filtered through a 0.2 μm filter. The resist was spin-coated on a 12″ silicon wafer which consists of 42 nm thickness coating of Dow Chemical AR40 anti-reflective layer on top of LTO (low temperature oxide) and SiCOH (low k dielectric). The resist was post-applying baked (PAB) at 110° C. for 60 seconds and exposed to 193 nm wavelength light on an ASML stepper (0.93 NA, 0.84 outer and 0.59 inner a annular illumination). The wafer was then post-exposure baked (PEB) at 130° C. for 60 seconds. It was developed using a single puddle develop process for 30 seconds with PGMEA as the developer. A 55 nm space on 178 nm pitch feature was resolved using a bright field mask.

### Example 2

### Resist B Formulation

A tetrapolymer consisting of 10 mole % McpMA, 40 mole % MAdMA, 15 mole % HEAdMA and 35 mole % NLM was dissolved in PGMEA with 30 wt % GBL, 5 wt % triphenyl-sulfonium 1,1,2,2,3,3,4,4,4-nonafluoro-butane-1-sulfonate and 0.33 wt % of piperidine-1-carboxylic acid tert-butyl ester (all wt % are relative to the polymer) to make a solution with 4 wt % of solid content. The resulting solution was filtered through a 0.2 μm filter. The resist was spin-coated on a 12″ silicon wafer which consists of 42 nm thickness coating of Dow Chemical AR40 anti-reflective layer on top of LTO (low temperature oxide) and SiCOH (low k dielectric). The resist was post-applying baked (PAB) at 110° C. for 60 seconds and exposed to 193 nm wavelength light on an ASML stepper (0.93 NA, 0.84 outer and 0.59 inner σ annular illumination). The wafer was then post-exposure baked (PEB) at 120° C. for 60 seconds. It was developed using a single puddle develop process for 30 seconds with PGMEA as the developer. A 120 nm space on 400 nm pitch feature was resolved using a bright field mask.

### Example 3

### Resist C Formulation

A copolymer consisting of 50 mole % MAdMA and 50 mole % GMA was dissolved in PGMEA with 30 wt % GBL, 7 wt % triphenyl-sulfonium 1,1,2,2,3,3,4,4,4-nonafluoro-butane-1-sulfonate and 0.82 wt % of piperidine-1-carboxylic acid tert-butyl ester (all wt % are relative to the polymer) to make a solution with 4 wt % of solid content. The resulting solution was filtered through a 0.2 μm filter. The resist was spin-coated on a 12″ silicon wafer which consists of 42 nm thickness coating of Dow Chemical AR40 anti-reflective layer on top of LTO (low temperature oxide) and SiCOH (low k dielectric). The resist was post-applying baked (PAB) at 110° C. for 60 seconds and exposed to 193 nm wavelength light on an ASML stepper (0.93 NA, 0.84 outer and 0.59 inner a annular illumination). The wafer was then post-exposure baked (PEB) at 110° C. for 60 seconds. It was developed using a single puddle develop process for 30 seconds with PGMEA solvent developer. Lithography resolution was poor using a bright field mask.

### Example 4

### Resist D Formulation

A terpolymer consisting of 25 mole % EcoMA, 25 mole % EcpMA and 50 mole % NLM was dissolved in PGMEA with 10 wt % of GMA homopolymer, 30 wt % GBL, 7 wt % triphenyl-sulfonium 1,1,2,2,3,3,4,4,4-Nonafluoro-butane-1-sulfonate and 0.73 wt % of 1-tert-butyloxycarbonyl-2-phenyl benzimidazole (all wt % are relative to the polymer) to make a solution with 4 wt % of solid content. The resulting solution was filtered through a 0.2 μm filter. The resist was spin-coated on a 12″ silicon wafer which consists of 42 nm thickness coating of Dow Chemical AR40 anti-reflective layer on top of LTO (low temperature oxide) and SiCOH (low k dielectric). The resist was post-applying baked (PAB) at 100° C. for 60 seconds and exposed to 193 nm wavelength light on an ASML stepper (0.93 NA, 0.84 outer and 0.59 inner σ annular illumination). The wafer was then post-exposure baked (PEB) at 90° C. for 60 seconds. It was developed using a single puddle develop process for 30 seconds with PGMEA solvent developer. A 50 nm space on 390 nm pitch feature was resolved using a bright field mask.

While the present invention has been particularly shown and described with respect to preferred embodiments, it will be understood by those skilled in the art that the foregoing and other changes in forms and details may be made without departing from the spirit and scope of the invention. It is therefore intended that the present invention not be limited to the exact forms and details described and illustrated but fall within the scope of the appended claims.

What is claimed is:

1. A photoresist composition capable of negative development comprising an imaging polymer and a radiation sensitive acid generator, said imaging polymer comprising a first monomeric unit having a pendant acid labile moiety and a second monomeric unit containing a reactive ether moiety, an isocyanide moiety or an isocyanate moiety.

2. The photoresist composition of claim 1, wherein said acid-labile pendant moiety comprises one of a tertiary alkyl carbonate, a tertiary alkyl ester, a tertiary alkyl ether, an acetal and a ketal.

3. The photoresist composition of claim 2, wherein said acid-labile pendant moiety comprises a tertiary alkyl ester.

4. The photoresist composition of claim 1, wherein said reactive ether moiety is epoxide.

5. The photoresist composition of claim 1, wherein said radiation sensitive acid generator comprises at least one of an onium salt, a succinimide derivative, a diazo compound, and a nitrobenzyl compound.

6. The photoresist composition of claim 1, further comprising at least one of a solvent, a quencher, and a surfactant.

7. The photoresist composition of claim 6, wherein said solvent comprises at least one of an ether, a glycol ether, an aromatic hydrocarbon, a ketone, and an ester.

8. The photoresist composition of claim 7, wherein said photoresist composition comprises:
about 1 to about 30 wt. % of said imaging polymer;
about 0.5 to about 30 wt. % of said radiation sensitive acid generator, based on the total weight of said imaging polymer; and
about 70 to about 99 wt. % of said solvent.

9. A photoresist composition capable of negative development comprising a polymer, a radiation sensitive acid generator and a component, said polymer comprising a monomeric unit having a pendant acid labile moiety, and said component comprising an alcohol moiety, a reactive ether moiety, an isocyanide moiety or an isocyanate moiety.

10. The photoresist composition of claim 9, wherein said reactive ether moiety is epoxide.

11. The photoresist composition of claim 9, further comprising at least one of a solvent, a quencher, and a surfactant.

12. The photoresist composition of claim 11, wherein said photoresist composition comprises:
about 1 to about 30 wt. % of said polymer;
about 0.5 to about 30 wt. % of said radiation sensitive acid generator, based on the total weight of said polymer;
about 1 to about 30 wt. % of said component, based on the total weight of said polymer; and
about 70 to about 99 wt. % of said solvent.

13. A method of forming a patterned material structure on a substrate, said method comprising:
providing a substrate with a layer of said material;
applying a photoresist composition to said substrate to form a photoresist layer over said material layer, said photoresist composition comprising an imaging polymer and a radiation sensitive acid generator, said imaging polymer comprising a first monomeric unit having a pendant acid labile moiety and a second monomeric unit containing a primary alcohol moiety, a secondary alcohol moiety, a reactive ether moiety, an isocyanide moiety or an isocyanate moiety;
patternwise exposing said substrate to radiation whereby acid is generated by said radiation sensitive acid generator in exposed regions of said photoresist layer by said radiation; and
contacting said photoresist layer with a developer comprising an organic solvent whereby unexposed regions of said photoresist layer are selectively removed by said developer solution to form a patterned structure in said photoresist layer.

14. The method of claim 13, further comprising:
transferring said patterned structure to said material layer.

15. The method of claim 13, wherein said developer is selected from a group consisting of ethers, glycol ethers, aromatic hydrocarbons, ketones, esters and a combination of two or more of the foregoing solvents.

16. The method of claim 13, further comprising:
rinsing said photoresist layer with a second organic solvent after said contacting step.

17. The method of claim 16, wherein said second organic solvent is selected from a group consisting of 1-butanol, methanol, ethanol, 1-propanol, ethylene glycol, 1,2-butanediol, 1,3-butanediol, 1,4-butanediol, 1,2-propanediol, 1-methyl-2-butanol, 1-pentanol, 2-pentanol, 3-pentanol, 1-hexanol, 2-hexanol, 3-hexanol, 1-heptanol, 2-heptanol, 3-heptanol, 4-heptanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 2,4-dimethyl-3-pentanol, 3-ethyl-2-pentanol, 1-methylcyclopentanol, 2-methyl-1-hexanol, 2-methyl-2-hexanol, 2-methyl-3-hexanol, 3-methyl-3-hexanol, 4-methyl-3-hexanol, 5-methyl-1-hexanol, 5-methyl-2-hexanol, 5-methyl-3-hexanol, 4-methylcyclohexanol, 1,3-propanediol, and a combination of two or more of the foregoing solvents.

18. The method of claim 13, further comprising, after said patternwise exposing step and before said contacting step, baking said substrate at a temperature from about 70° C. to about 150° C.

19. The method of claim 13, wherein said acid-labile pendant moiety comprises one of a tertiary alkyl carbonate, a tertiary alkyl ester, a tertiary alkyl ether, an acetal and a ketal.

20. The method of claim 13, wherein said reactive ether moiety is epoxide.

21. The method of claim 13, wherein said photoresist composition further comprises at least one of a solvent, a quencher, and a surfactant.

22. A method of forming a patterned material structure on a substrate, said method comprising:
providing a substrate with a layer of said material;
applying a photoresist composition to said substrate to form a photoresist layer over said material layer, said photoresist composition comprising a polymer, a radiation sensitive acid generator and a component, said polymer comprising a monomeric unit having a pendant acid labile moiety, and said component comprising an alcohol moiety, a reactive ether moiety, an isocyanide moiety or an isocyanate moiety;
patternwise exposing said substrate to radiation whereby acid is generated by said radiation sensitive acid generator in exposed regions of said photoresist layer by said radiation; and
contacting said photoresist layer with a developer comprising an organic solvent whereby unexposed regions of said photoresist layer are selectively removed by said developer solution to form a patterned structure in said photoresist layer.

23. The method of claim 22, further comprising:
transferring said patterned structure to said material layer.

24. The method of claim 22, wherein said developer is selected from a group consisting of ethers, glycol ethers, aromatic hydrocarbons, ketones, esters and a combination of two or more of the foregoing solvents.

25. The method of claim 22, further comprising, after said patternwise exposing step and before said contacting step, baking said substrate at a temperature from about 70° C. to about 150° C.

26. The method of claim 22, wherein said photoresist composition further comprises at least one of a solvent, a quencher, and a surfactant.
